(19) United States
(12) Patent Application Publication
(10) Pub. No.: US 2025/0309167 A1
(43) Pub. Date: Oct. 2, 2025

(54) CONDUCTIVE POST WITH FOOTING PROFILE

(71) Applicant: TAIWAN SEMICONDUCTOR MANUFACTURING COMPANY, LTD., Hsinchu (TW)

(72) Inventors: Tzu-Yang LIN, Tainan City (TW); Chen-Yu LIU, Kaohsiung City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/621,673

(22) Filed: Mar. 29, 2024

(51) Int. Cl. H01L 23/00; G03F 7/004; G03F 7/028; G03F 7/20; H01L 23/528

(52) U.S. Cl. CPC H01L 24/13; G03F 7/0045; G03F 7/028; G03F 7/2043; H01L 23/5283; H01L 24/11; H01L 2224/0362; H01L 2224/0401

(57) ABSTRACT

A method comprises the following steps. A photoresist composition is applied over an under bump metallurgy (UBM) layer to form a photoresist layer. The photoresist composition comprises a polymer, a crosslinker and a photo initiator. The photo initiator is a floating photo initiator. The photo initiator has a first concentration in a top portion of the photoresist layer and a second concentration in a bottom portion of the photoresist layer. The first concentration is greater than the second concentration. The photoresist layer is exposed. The photoresist layer is developed using a developer. A conductive layer is formed over the UBM layer. After forming the conductive layer over the UBM layer, the photoresist layer is removed.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIG. 1 is a flowchart illustrating a method for fabricating a semiconductor structure, in accordance with some embodiments of the present disclosure.

FIGS. 2 through 11 are cross-sectional views of a semiconductor structure at various fabrication stages, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

In testing and etching processes for under bump metallurgy (UBM) removal, thermal stress would cause undesired cracks in an underfill material, a passivation layer, or a redistribution layer (RDL). As pitches are tighten, such thermal stress may be increased. Dual photoresist films made of different photosensitive materials and thicknesses (e.g., a first photoresist film and a second photoresist film over the first photoresist film) over the UBM layer may be used to form a conductive post with a footing profile to reduce thermal stress. After an exposure of a lithography process is performed, a first opening with a substantially vertical sidewall is formed in a first photoresist film, and a second opening with a sloped sidewall is formed in a second photoresist film. The second opening has a top diameter and a bottom diameter greater than the top diameter. A conductive layer is then formed in the first opening and the second opening followed by removing the dual photoresist films. However, it has low efficiency, difficult to tighten pitches and control critical dimension (CD) uniformity. Further, forming the dual photoresist films with fine pitches and undercut, and the lithography performance are difficult to be controlled.

The present disclosure provides a method of forming a conductive post with a footing profile using a novel photoresist. The novel photoresist has different shrinkage amounts and dissolution rates between a top portion and a bottom portion thereof, and thus can provide an undercut for forming the footing profile of the conductive post. By using the novel photoresist, an undercut size can reach about 10% of the CD in which the CD is about 1 μm to 6 μm.

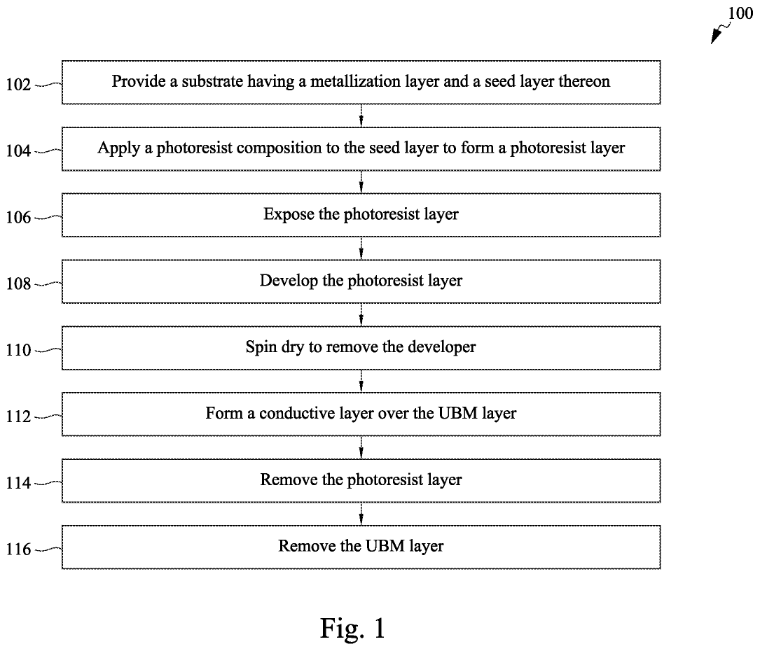

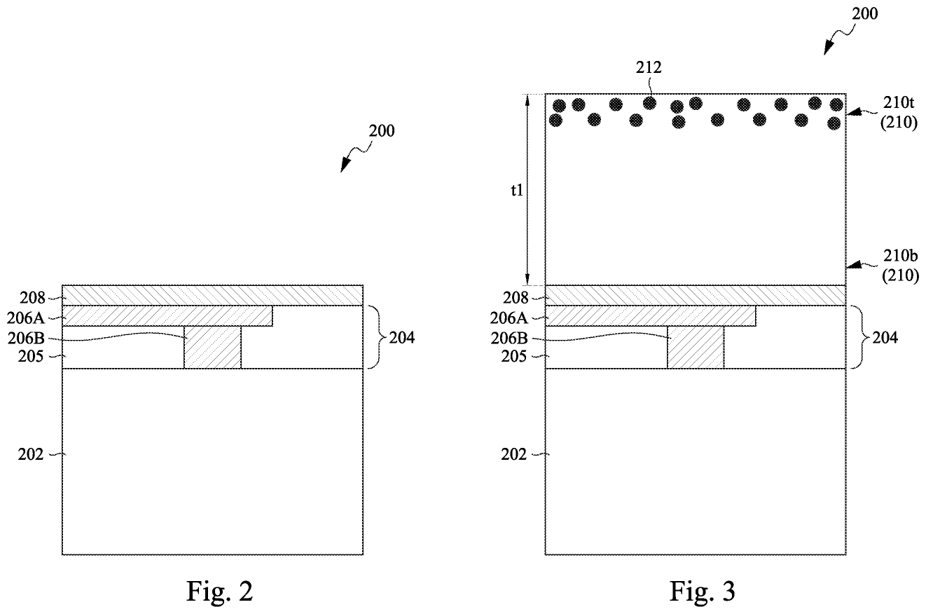

FIG. 1 is a flowchart illustrating a method 100 for fabricating a semiconductor structure, in accordance with some embodiments of the present disclosure. FIGS. 2 through 11 are cross-sectional views of a semiconductor structure 200 at various fabrication stages, in accordance with some embodiments. The method 100 is described below in conjunction with FIG. 1 and FIGS. 2 through 11 wherein the semiconductor structure 200 is fabricated by using embodiments of the method 100. It is understood that additional steps can be provided before, during, and after the method 100, and some of the steps described below can be replaced or eliminated, for additional embodiments of the method 100. It is further understood that additional features can be added in the semiconductor structure 200, and some of the features described below can be replaced or eliminated, for additional embodiments of the semiconductor structure 200.

The semiconductor structure 200 may be an intermediate structure during the fabrication of an IC, or a portion thereof. The IC may include logic circuits, memory structures, passive components (such as resistors, capacitors, and inductors), and active components such as diodes, field-effect transistors (FETs), metal-oxide semiconductor field effect transistors (MOSFETs), complementary metal-oxide semiconductor (CMOS) transistors, bipolar transistors, high voltage transistors, high frequency transistors, fin-like FETs (FinFETs), other three-dimensional (3D) FETs, and combinations thereof. The semiconductor structure 200 may include a plurality of semiconductor devices (e.g., transistors), which may be interconnected.

Referring to FIGS. 1 and 2, the method 100 includes an operation 102, in which a substrate 202 having an interconnect structure 204 and an under-bump-metallurgy (UBM) layer 208 formed thereon is provided, in accordance with some embodiments. FIG. 2 is a cross-sectional view of the semiconductor structure 200 including the substrate 202 and the interconnect structure 204, in accordance with some embodiments. The interconnect structure 204 includes an interlayer dielectric (ILD) layer 205, a conductive line 206A and a conductive via 206B.

In some embodiments, the substrate 202 may be a bulk semiconductor substrate including one or more semiconductor materials. In some embodiments, the substrate 202 may include silicon, silicon germanium, carbon doped silicon (Si:C), silicon germanium carbide, or other suitable semiconductor materials. In some embodiments, the substrate 202 is composed entirely of silicon.

In some embodiments, the substrate 202 may include one or more epitaxial layers formed on a top surface of a bulk semiconductor substrate. In some embodiments, the one or more epitaxial layers introduce strains in the substrate 202 for performance enhancement. For example, the epitaxial layer includes a semiconductor material different from that of the bulk semiconductor substrate, such as a layer of silicon germanium overlying bulk silicon or a layer of silicon overlying bulk silicon germanium. In some embodiments, the epitaxial layer(s) incorporated in the substrate 202 are formed by selective epitaxial growth, such as, for example, metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), or combinations thereof.

In some embodiments, the substrate 202 may be a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or other suitable technique, such as wafer bonding and grinding.

In some embodiments, the substrate 202 may also include a dielectric substrate such as silicon oxide, silicon nitride, silicon oxynitride, a low-k dielectric, silicon carbide, and/or other suitable layers.

In some embodiments, the substrate 202 may also include various p-type doped regions and/or n-type doped regions, implemented by a process such as ion implantation and/or diffusion. Those doped regions include n-well, p-well, lightly doped region (LDD) and various channel doping profiles configured to form various IC devices, such as a CMOS transistor, imaging sensor, and/or light emitting diode (LED). The substrate 202 may further include other functional features such as a resistor and/or a capacitor formed in and/or on the substrate 202.

In some embodiments, the substrate 202 may also include various isolation features. The isolation features separate various device regions in the substrate 202. The isolation features include different structures formed by using different processing technologies. For example, the isolation features may include shallow trench isolation (STI) features. The formation of an STI may include etching a trench in the substrate 202 and filling in the trench with insulator materials such as silicon oxide, silicon nitride, and/or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

In some embodiments, the substrate 202 may also include gate stacks formed by dielectric layers and electrode layers. The dielectric layers may include an interfacial layer and a high-k dielectric layer deposited by suitable techniques, such as chemical vapor deposition (CVD), atomic layer deposition (ALD), physical vapor deposition (PVD), thermal oxidation, combinations thereof, and/or other suitable techniques. The interfacial layer may include silicon dioxide and the high-k dielectric layer may include LaO, AlO, ZrO, TiO, Ta₂O₅, Y₂O₃, SrTiO₃, BaTiO₃, BaZrO, HfZrO, HfLaO, HfSiO, LaSiO, AlSiO, HfTaO, HfTIO, (Ba, Sr)TiO₃ (BST), Al₂O₃, Si₃N₄, SiON, and/or other suitable materials. The electrode layer may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide. The electrode layer may include Ti, Ag, Al, TiAlN, TaC, TaCN, TaSiN, Mn, Zr, TiN, TaN, Ru, Mo, Al, WN, Cu, W, any suitable materials, and/or a combination thereof.

In some embodiments, the substrate 202 may also include a plurality of inter-level dielectric (ILD) layers and conductive features integrated to form an interconnect structure configured to couple the various p-type and n-type doped regions and the other functional features (such as gate electrodes), resulting in a functional integrated circuit. In FIG. 2, a topmost metallization layer, e.g., metallization layer including the conductive line 206, is illustrated and described.

In some embodiments, the conductive line 206A provides horizontal electrical routing, while the conductive via 206B provides vertical connection between conductive lines in different metallization layers. The interconnect structure 204 may be formed through any suitable process such as deposition, damascene, dual damascene, etc. Although a single interconnect structure is illustrated, any number of interconnect structures is contemplated.

Still referring to FIG. 2, the UBM layer 208 is formed on the interconnect structure 204. In some embodiments, the UBM layer 208 includes a first layer serving as a diffusion barrier layer or a glue layer, which is formed of titanium, tantalum, titanium nitride, tantalum nitride, or the like by physical vapor deposition (PVD) or sputtering. In some embodiments, the UBM layer 208 includes a second layer serving as a seed layer, which is formed of copper or copper alloys by physical vapor deposition (PVD) or sputtering. In some embodiments, such the UBM layer 208 is a conformal layer. That is, the UBM layer 208 has a substantially equal thickness extending along the region on which the UBM layer 208 is formed.

Referring to FIGS. 1 and 3, the method 100 proceeds to an operation 104, in which a photoresist composition is applied on the UBM layer 208 to form a photoresist layer 210. The photoresist composition applied on the UBM layer 208 to form the photoresist layer 210 may be applied by spin coating process or deposition process. The photoresist composition may include a polymer, a crosslinker, a photo initiator 212, dye, or a combination thereof. In some embodiments, the photoresist composition may include a solvent in which the polymer, the crosslinker, the photo initiator 212 and the dye are dissolved in the solvent. In some embodiments, the photoresist layer 210 has a thickness t1 in a range from about 3 μm to about 10 μm, and hence the photoresist layer 210 has an enough budget for a subsequent plating process. The photo initiator 212 is an initiator that can be generated photo-chemically and induce the polymerization of the radiation-curable groups of the polymer. In some embodiments, the photo initiator 212 is in a range from about 0.01 weight percent (wt %) to about 5 weight percent (wt %) of a total solid weight of the photoresist composition.

In some embodiments, the photo initiator 212 is a floating photo initiator. For example, the photo initiator 212 can float to a top portion 210t of the photoresist layer 210, and thus the photo initiator 212 has a first concentration in the top portion 210t of the photoresist layer 210 greater than a second concentration in a bottom portion 210b of the photoresist layer 210. In some embodiments, the photo initiator 212 further comprises a photo acid generator (PAG). In some embodiments, the PAG is in a range from about 0.01 wt % to about 5 wt % of the total solid weight of the photoresist composition. The PAG is a floating PAG. The PAG can float to the top portion 210t of the photoresist layer 210 and thus the PAG has a first concentration in the top portion 210t of the photoresist layer 210 greater than a second concentration in the bottom portion 210b of the photoresist layer 210. In some other embodiments, a sum of concentrations of the photo initiator 212 and the PAG is in a range from about 0.01 wt % to about 5 wt % of the total solid weight of the photoresist composition. In some embodiments, the photo initiator 212 can be represented by a formula (1), and the PAG can be represented by a formula (2):

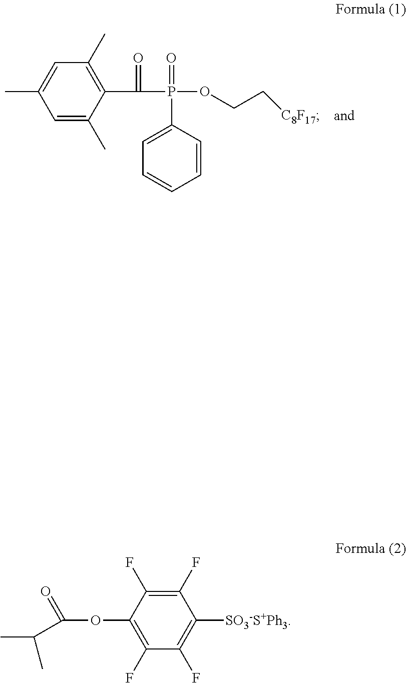

In some embodiments, the crosslinker of the photoresist composition has a double bond and thus can self-crosslink to control a dissolution rate of the photoresist layer 210. In some embodiments, the crosslinker is in a range from about 30 wt % to about 50 wt % of the total solid weight of the photoresist composition. In some embodiments, the crosslinker can be represented by formulae (3) to (4):

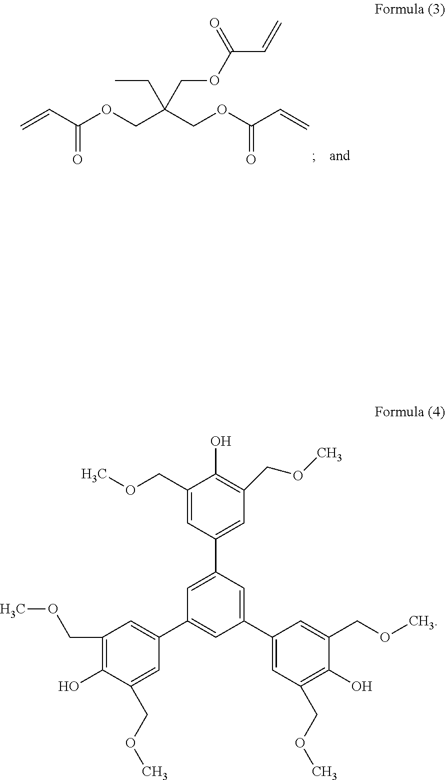

In some embodiments, the polymer of the photoresist composition can include a novolak resin, an acrylic type resin, a poly hydroxy styrene, or a combination thereof. The novolak resin may be in a range from about 0 wt % to about 30 wt % of the total solid weight of the photoresist composition. The acrylic type resin may be in a range from about 5 wt % to about 10 wt % of the total solid weight of the photoresist composition. The poly hydroxy styrene may be in a range from about 20 wt % to about 40 wt % of the total solid weight of the photoresist composition. In some embodiments, the novolak resin has a repeating unit represented by a formula (5), the acrylic type resin has a repeating unit represented by a formula (6), and the poly hydroxy styrene has a repeating unit represented by a formula (7):

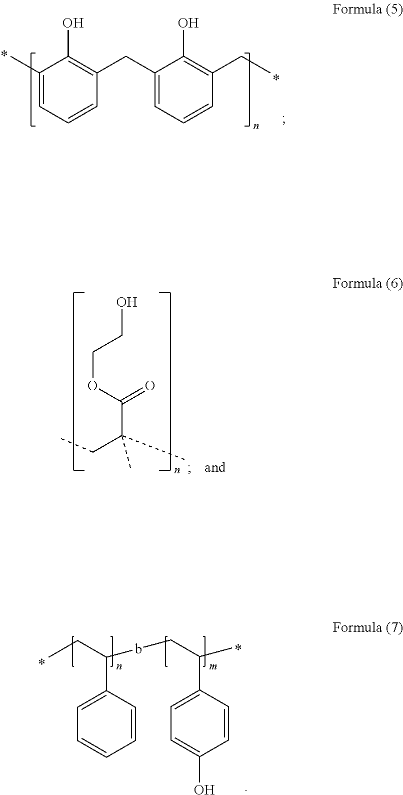

In some embodiments, n in the formula (5) can be an integer of 1 to 5, n in the formula (6) can be an integer of 1 to 5, n in the formula (7) can be an integer of 1 to 5 and m in the formula (7) can be an integer of 1 to 5.

In some embodiments, a soft bake (SB) operation may be performed to the photoresist layer 210 to reduce solvent in the photoresist layer 210. For example, the solvent may be partially removed by the soft bake operation.

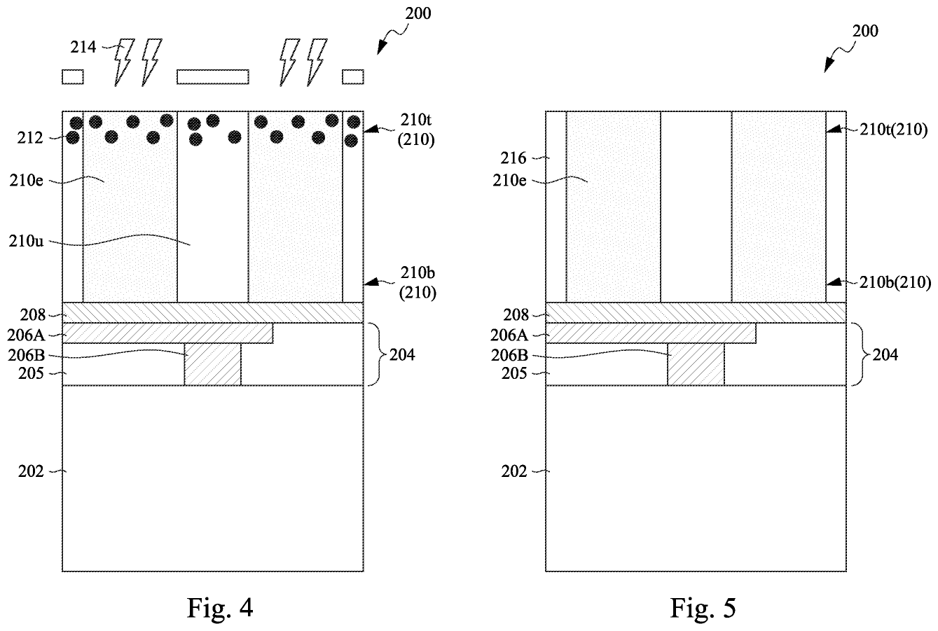

Referring to FIGS. 1 and 4, the method 100 proceeds to an operation 106, in which the photoresist layer 210 is exposed to an actinic radiation 214. With reference to FIGS. 1 and 4, in some embodiments of the operation 106, the photoresist layer 210 is exposed to an actinic radiation 214. In some embodiments, the photoresist layer 210 is exposed to the actinic radiation 214 with an illumination wavelength which is substantially less than about 250 nm. For example, the actinic radiation 214 may include at least one of the KrF, ArF, extreme ultraviolet (EUV) radiation, E-beam or the like. The photoresist layer 210 may include an exposed photoresist 210e and an unexposed photoresist 210u. Since the photo initiator 212 has the first concentration in the top portion 210t of the photoresist layer 210 greater than the second concentration in the bottom portion 210b of the photoresist layer, the top portion 210t of the photoresist layer 210 has a crosslink reaction level higher than a crosslink reaction level of the bottom portion 210b of the photoresist layer 210. The difference between the crosslink reaction levels of the top portion 210t and the bottom portion 210b can lead to different crosslink levels, different dissolution rates and different densities therebetween. The top portion 210t of the photoresist layer 210 has a density higher than a density of the bottom portion 210b of the photoresist layer 210. The top portion 210t of the photoresist layer 210 has a dissolution rate to a developer lower than a dissolution rate to the developer of the bottom portion 210b.

Referring to FIGS. 1 and 5, the method 100 proceeds to an operation 108, in which the photoresist layer 210 is developed using a developer. With reference to FIGS. 1 and 5, in some embodiments of the operation 108, the photoresist layer 210 is developed using a developer 216. The developer may be an aqueous-based developer, such as a tetramethylammonium hydroxide (TMAH) solution or an organic solvent, such as n-butyl acetate (nBA).

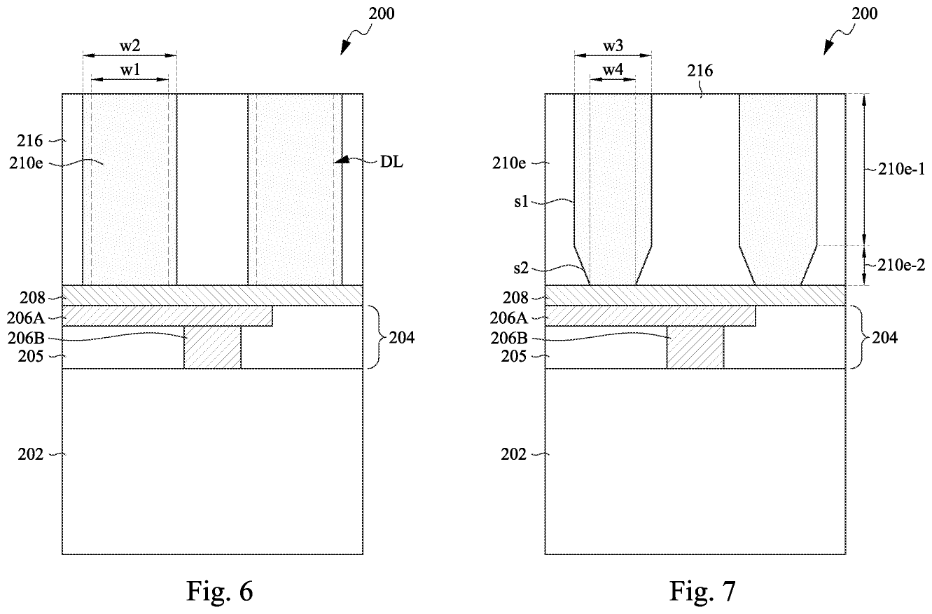

Referring to FIGS. 1 and 6, the unexposed photoresist 210u is removed by the developer 216 and the exposed photoresist 210e remains over the UBM layer 208. The exposed photoresist 210e is swelled up due to the developer 216 penetrating into the photoresist layer 210. Therefore, the exposed photoresist 210e has an increased volume. In other words, the exposed photoresist 210e after the operation 108 has a volume greater than a volume of the exposed photoresist 210e before the operation 108. Edges of the exposed photoresist 210e before the operation 108 are shown as dotted lines DL. In other words, from a cross-sectional view, the exposed photoresist 210e after the operation 108 may have a width w2, and the exposed photoresist 210e before the operation 108 may have width w1 less than the width w2.

Referring to FIGS. 1 and 7, as discussed above with regard to FIG. 3, due to the top portion 210t having the dissolution rate to the developer lower than the dissolution rate to the developer of the bottom portion 210b, the bottom portion 210b has a dissolved amount greater than a dissolved amount than the top portion 210t. That is, the bottom portion 210b has a shrinkage amount greater than a shrinkage amount of the top portion 210t. For example, the exposed photoresist 210e may have a top width w3 and a bottom width w4 less than the top width w3. That is, the exposed photoresist 210e may have a desired undercut profile. For example, an undercut size of the exposed photoresist 210e can reach about 10% of the CD in which the CD is about 1 μm to 6 μm. In some embodiments, the exposed photoresist 210e has a first sidewall S1 and a second sidewall S2 under the first sidewall S1. The first sidewall S1 is substantially vertical to a top surface of the UBM layer 208, and the second sidewall S2 is inclined with respect to the top surface of the UBM layer 208. That is, the exposed photoresist 210e may have an upper portion 210e-1 with a substantially constant width and a lower portion 210e-2 under the upper portion 210e-1, and the lower portion 210e-2 has a varying width decreasing in a direction toward the UBM layer 208. In other words, the lower portion 210e-2 of the exposed photoresist 210e has a width decreasing in a direction toward the UBM layer 208.

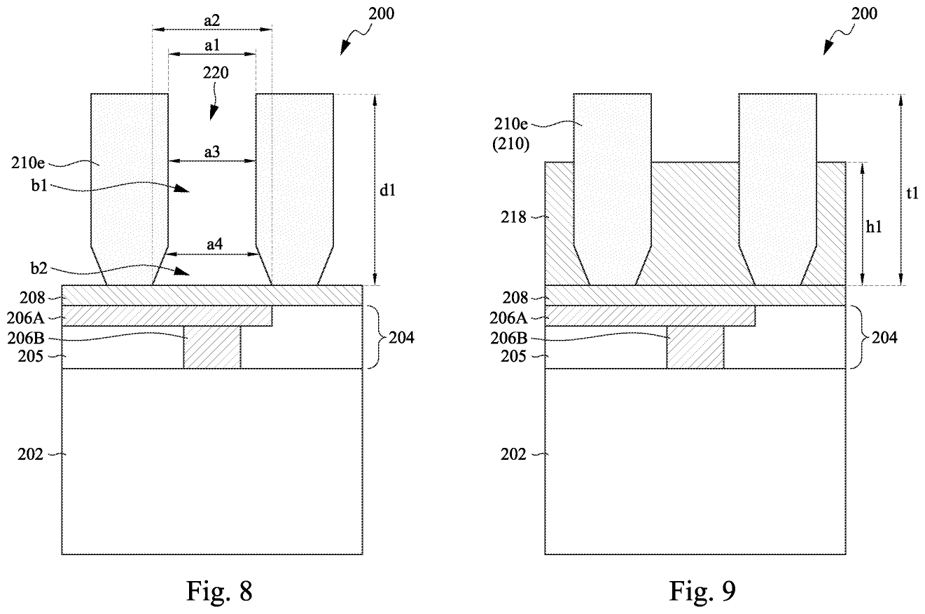

Referring to FIGS. 1 and 8, the method 100 proceeds to an operation 110, in which a spin drying is performed to remove the developer. With reference to FIGS. 1 and 8, in some embodiments of the operation 110, a spin drying is performed to remove the developer 216 (see FIG. 7), exposing the top surface of the UBM layer 208. For example, the spin drying includes holding the substrate 202 and rotating the substrate 202 to spin off the developer 216 from the photoresist layer 210 and the UBM layer 208. Openings 220 are between two adjacent exposed photoresists 210e. In some embodiments, the openings 220 have a high aspect ratio such as 4.5±0.5. In some embodiments, peeling of the exposed photoresist 210e from the UBM layer 208 may not occur during the spin drying.

The openings 220 each have a top width a1 and a bottom width a2, and the bottom width a2 is greater than the top width a1. Each of the openings 220 of the exposed photoresist 210e has an upper portion b1 and a lower portion b2 having a greater width variation than the upper portion b1. The upper portion b1 of each of the openings 220 of the exposed photoresist 210e has a substantially constant width a3. The lower portion b2 of each of the openings of the exposed photoresist 210e has a width a4 decreasing as a distance from the UBM layer 208 increases. The openings 220 may have a depth d1 along a vertical direction.

Referring to FIGS. 1 and 9, the method 100 proceeds to an operation 112, in which a conductive layer is formed over the UBM layer. With reference to FIGS. 1 and 9, in some embodiments of the operation 112, a conductive layer 218 is formed on the UBM layer 208 and is in contact with the top surface of UBM layer and the lower portion of the exposed photoresist 210e of the photoresist layer 210. That is, the conductive layer 218 is formed in the openings 220 (see FIG. 8) in the exposed photoresist 210e. The conductive layer 218 surrounds a bottom of the exposed photoresist 210e. In some embodiments, the conductive layer 218 is a copper (Cu) layer and the deposition of copper layer may be continuously performed to reach a predetermined height h1. The height h1 of the conductive layer 218 is less than the depth d1 of the opening 220 (see FIG. 8). As used throughout this disclosure, the term “copper (Cu) layer” is intended to include substantially a layer including pure elemental copper, copper containing unavoidable impurities, or copper alloys containing minor amounts of elements such as tantalum, indium, tin, zinc, manganese, chromium, titanium, germanium, strontium, platinum, magnesium, aluminum, or zirconium. The formation methods may include sputtering, printing, electro plating, electroless plating, or chemical vapor deposition (CVD) methods. For example, electro-chemical plating (ECP) is carried out to form the copper layer. In some embodiments, the ECP process using a low initial deposition rate is performed to cause a “gap filling” effect, which enables the plated copper layer to fill the openings 220 between the exposed photoresist 210e, resulting in the footing profile in the conductive layer in proximity to the UBM layer 208. The exposed photoresist 210e has the thickness t1 in a range from about 3 μm to about 10 μm, and hence the exposed photoresist 210e may not deform during forming the conductive layer 218. That is, the exposed photoresist 210e can stand damage from forming the conductive layer 218.

In other embodiments, the Cu deposition process of the copper layer may be controlled to fill the openings 220, making the top surface level with or higher than the top surface of the exposed photoresist 210e which are not shown in the figures.

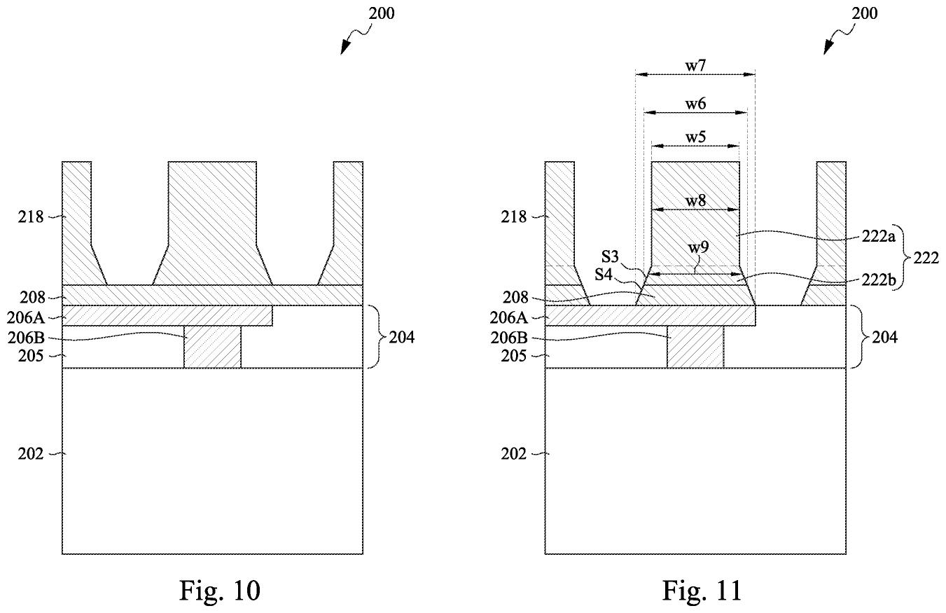

Referring to FIGS. 1 and 10, the method 100 proceeds to an operation 114, in which the exposed photoresist 210e is removed. With reference to FIGS. 1 and 10, in some embodiments of the operation 114, after forming the conductive layer 218, the exposed photoresist 210e is removed by using a suitable photoresist stripper solvent or by a photoresist ashing operation. The exposed photoresist 210e may not remain over the UBM layer 208 after operation 114.

Referring to FIGS. 1 and 11, the method 100 proceeds to operation 116, in which the UBM layer 208 is etched. With reference to FIGS. 1 and 11, in some embodiments of the operation 114, the UBM layer 208 is etched. In some embodiments, a wet etching is performed to etched the exposed the UBM layer 208, exposing the underlying ILD layer 205 which is under the UBM layer 208. The wet etching may include exposure to an acid vapor and then a de-ionized (DI) water rinse. In some embodiments, the wet etching is capable of removing oxide films that may form on an exposed surface of the conductive layer 218.

The conductive layer 218 can be referred to as a conductive post 222, a bump structure or a copper pillar bump. The conductive post 222 is used to couple to an overlying conductive connection (not shown). Instead of using a solder bump, the conductive post 222 can provide electrical connection of a given electronic component to the conductive line 206A of the interconnect structure 204, which achieves finer pitch with minimum probability of bump bridging. For advanced packaging of IC dies with many function circuitries, the conductive post 222 has a relatively small size to enable more bumps to connect to an in input/output (I/O) of chip (not shown), and hence the conductive post 222 may also be called micro-bumps.

The conductive post 222 can have a footing profile such that in testing and etching processes for the UBM layer 208 removal, the thermal stress would be prevented. The conductive post 222 has a topmost width w5 and a bottommost width w6 greater than the topmost width w5. For example, the conductive post 222 includes an upper portion 222a and a lower portion 222b under the upper portion 222a. Each of the conductive posts 222 has the upper portion 222a and the lower portion 222b having a greater width variation than the upper portion 222a. The upper portion 222a has a substantially constant width w8. That is, the upper portion 222a has the width w8 remaining substantially constant as a distance from the UBM layer 208 increases. The lower portion 222b has a width w9 decreasing as a distance from the UBM layer 208 increases. The lower portion 222b has opposite inclined sidewalls S3 with respect to the top surface of the substrate 202. Similarly, the UBM layer 208 may have a width increasing in a direction toward the substrate 202. In some embodiments, the UBM layer 218 has a bottommost width w7 greater than the topmost width w5 of the conductive post 222. In some embodiments, the conductive post 222 and the UBM layer 208 have an interface with a width greater than the topmost width w5 of the conductive post 222. The UBM layer 208 has opposite inclined sidewalls S4 with respect to the top surface of the substrate 202. In some embodiments, the inclined sidewalls S3 terminate at the inclined sidewalls S4.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that by forming a conductive post with a footing profile using a novel photoresist, the novel photoresist has different shrinkage amounts and dissolution rates between a top portion and a bottom portion thereof, and thus can provide an undercut for forming the footing profile of the conductive post. Another advantage is that by using the novel photoresist, an undercut size can reach about 10% of the CD in which the CD is about 1 μm to 6 μm.

In some embodiments, a method comprises the following steps. A photoresist composition is applied over an under bump metallurgy (UBM) layer to form a photoresist layer, wherein the photoresist composition comprises a polymer, a crosslinker, and a photo initiator, wherein the photo initiator is a floating photo initiator, the photo initiator has a first concentration in a top portion of the photoresist layer and a second concentration in a bottom portion of the photoresist layer, and the first concentration is greater than the second concentration. The photoresist layer is exposed. The photoresist layer is developed using a developer. A conductive layer is formed over the UBM layer. After forming the conductive layer over the UBM layer, the photoresist layer is removed. In some embodiments, the photo initiator is represented by a formula (1):

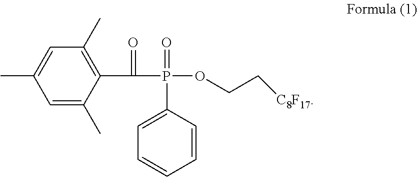

In some embodiments, the photoresist composition further comprises a photo acid generator, wherein the photo acid generator is a floating photo acid generator, the photo acid generator has a third concentration in the top portion of the photoresist layer and a fourth concentration in the bottom portion of the photoresist layer, and the third concentration is greater than the fourth concentration. In some embodiments, the photo acid generator is represented by a formula (2):

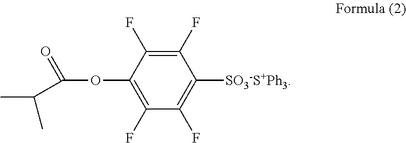

In some embodiments, after exposing the photoresist layer, the top portion of the photoresist layer has a density greater than a density of the bottom portion of the photoresist layer. In some embodiments, during developing the photoresist layer using the developer, the top portion of the photoresist layer has a dissolution rate to the developer higher than a dissolution rate of the bottom portion of the photoresist layer to the developer.

In some embodiments, a method comprises the following steps. A photoresist layer is formed over an under bump metallurgy (UBM) layer. The photoresist layer is exposed. The photoresist layer is patterned such that the patterned photoresist layer has openings each having a top width and a bottom width greater than the top width. Conductive posts are formed in the openings in the patterned photoresist layer. After forming the conductive posts, the patterned photoresist layer is removed. In some embodiments, each of the openings of the patterned photoresist layer has an upper portion and a lower portion having a greater width variation than the upper portion. In some embodiments, the upper portion of each of the openings of the patterned photoresist layer has a substantially constant width. In some embodiments, the lower portion of each of the openings of the patterned photoresist layer has a width decreasing as a distance from the UBM layer increases. In some embodiments, each of the conductive posts has a top width and a bottom width greater than the top width. In some embodiments, a height of the conductive posts is less than a depth of the openings of the patterned photoresist layer. In some embodiments, each of the conductive posts has an upper portion and a lower portion having a greater width variation than the upper portion. In some embodiments, the lower portion of each of the conductive posts has a width decreasing as a distance from the UBM layer increases. In some embodiments, the method further comprises after removing the patterned photoresist layer, performing a wet etching process on the UBM layer. In some embodiments, after performing the wet etching process, a dielectric layer under the UBM layer is exposed.

In some embodiments, a semiconductor structure comprises a substrate, an interconnect structure over the substrate, an under bump metallurgy (UBM) layer over the interconnect structure and a conductive post over the UBM layer. The interconnect structure comprises a conductive line embedded in an interlayer dielectric (ILD) layer. The UBM layer is in contact with the conductive line. The conductive post comprises a lower portion and an upper portion over the lower portion. The lower portion has a greater width variation than the upper portion. In some embodiments, the lower portion of the conductive post has a width decreasing as a distance from the UBM layer increases. In some embodiments, the upper portion of conductive post has a width remaining substantially constant as a distance from the UBM layer increases. In some embodiments, the conductive post has a topmost width and a bottommost width greater than the topmost width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
applying a photoresist composition over an under bump metallurgy (UBM) layer to form a photoresist layer, wherein the photoresist composition comprises:
a polymer;
a crosslinker; and
a photo initiator, wherein the photo initiator is a floating photo initiator, the photo initiator has a first concentration in a top portion of the photoresist layer and a second concentration in a bottom portion of the photoresist layer, and the first concentration is greater than the second concentration;
exposing the photoresist layer;
developing the photoresist layer using a developer;
forming a conductive layer over the UBM layer; and
after forming the conductive layer over the UBM layer, removing the photoresist layer.

2. The method of claim 1, wherein the photo initiator is represented by a formula (1):

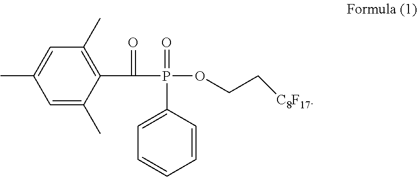

3. The method of claim 1, wherein the photoresist composition further comprises:
a photo acid generator, wherein the photo acid generator is a floating photo acid generator, the photo acid generator has a third concentration in the top portion of the photoresist layer and a fourth concentration in the bottom portion of the photoresist layer, and the third concentration is greater than the fourth concentration.

4. The method of claim 3, wherein the photo acid generator is represented by a formula (2):

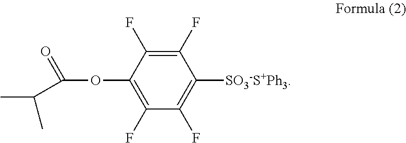

5. The method of claim 1, wherein after exposing the photoresist layer, the top portion of the photoresist layer has a density greater than a density of the bottom portion of the photoresist layer.

6. The method of claim 1, wherein during developing the photoresist layer using the developer, the top portion of the photoresist layer has a dissolution rate to the developer higher than a dissolution rate of the bottom portion of the photoresist layer to the developer.

7. A method, comprising:
forming a photoresist layer over an under bump metallurgy (UBM) layer;
exposing the photoresist layer;
patterning the photoresist layer such that the patterned photoresist layer has openings each having a top width and a bottom width greater than the top width;
forming conductive posts in the openings in the patterned photoresist layer; and
after forming the conductive posts, removing the patterned photoresist layer.

8. The method of claim 7, wherein each of the openings of the patterned photoresist layer has an upper portion and a lower portion having a greater width variation than the upper portion.

9. The method of claim 8, wherein the upper portion of each of the openings of the patterned photoresist layer has a substantially constant width.

10. The method of claim 8, wherein the lower portion of each of the openings of the patterned photoresist layer has a width decreasing as a distance from the UBM layer increases.

11. The method of claim 7, wherein each of the conductive posts has a top width and a bottom width greater than the top width.

12. The method of claim 7, wherein a height of the conductive posts is less than a depth of the openings of the patterned photoresist layer.

13. The method of claim 7, wherein each of the conductive posts has an upper portion and a lower portion having a greater width variation than the upper portion.

14. The method of claim 13, wherein the lower portion of each of the conductive posts has a width decreasing as a distance from the UBM layer increases.

15. The method of claim 7, further comprising:
after removing the patterned photoresist layer, performing a wet etching process on the UBM layer.

16. The method of claim 15, wherein after performing the wet etching process, a dielectric layer under the UBM layer is exposed.

17. A semiconductor structure, comprising:
a substrate;
an interconnect structure over the substrate, wherein the interconnect structure comprises a conductive line embedded in an interlayer dielectric (ILD) layer;
an under bump metallurgy (UBM) layer over the interconnect structure, wherein the UBM layer is in contact with the conductive line; and
a conductive post over the UBM layer, the conductive post comprising a lower portion and an upper portion over the lower portion, the lower portion having a greater width variation than the upper portion.

18. The semiconductor structure of claim 17, wherein the lower portion of the conductive post has a width decreasing as a distance from the UBM layer increases.

19. The semiconductor structure of claim 17, wherein the upper portion of the conductive post has a width remaining substantially constant as a distance from the UBM layer increases.

20. The semiconductor structure of claim 17, wherein the conductive post has a topmost width and a bottommost width greater than the topmost width.
